(19) United States
(12) Patent Application Publication
(10) Pub. No.: US 2026/0299021 A1
(43) Pub. Date: Oct. 1, 2026

(54) MULTI-PHASE SYNCHRONIZED METHOD FOR LANE MARGINING

(71) Applicant: SK hynix Inc., Gyeonggi-do (KR)

(72) Inventors: Chee Hoe Chu, San Jose, CA (US); Ping Zheng, Milpitas, CA (US); Chi Zhang, San Jose, CA (US); Priyadarsini Lanka, San Jose, CA (US); Zhengzhi Xiong, Milpitas, CA (US); Danny Segura, Santa Clara, CA (US)

(21) Appl. No.: 19/097,580

(22) Filed: Apr. 1, 2025

(51) Int. Cl. G01R 31/317; G01R 31/3185

(52) U.S. Cl. CPC G01R 31/31717; G01R 31/31727; G01R 31/318569

(57) ABSTRACT

A lane margining test for a plurality of lanes of an interconnect link may be performed using a multi-phase synchronized approach. A parallel margin assessment phase of the lane margining test may be performed on the plurality of lanes concurrently to determine a collective baseline offset. A serial margin assessment phase of the lane margining test may be performed sequentially on each lane starting at the collective baseline offset to determine a respective refined baseline offset for each lane beyond which a respective serial margin assessment phase fails for that lane. A fine tuning margin assessment phase of the lane margining test may be performed sequentially on each lane starting at the respective refined baseline offset for that lane to determine a respective lane margin for that lane.

### BACKGROUND

In systems using integrated circuit (IC) devices connected via an interconnect link having multiple lanes, signal performance can vary due to variation in the manufacturing process, electrical factors (e.g., voltage, temperature), environmental factors (e.g., electrical noise and interference), and the platform used by the device. Furthermore, performance variation and signal integrity degradation may increase with data transfer rates over the interconnect link. Lane margining is generally used to evaluate the electrical margin for each lane of the interconnect link to determine the signal quality under normal operating conditions, and how close to the edge of functionality the system can operate. Thus, lane margining can be used to evaluate the design before it starts experiencing errors, which can provide a robust and efficient system design.

### BRIEF SUMMARY

Techniques for performing a lane margining test for a plurality of lanes of an interconnect link using a multi-phase synchronized method are described. The lane margining test may be applied to an interconnect link between a peripheral device and a host device. The lane margining test may be performed while the interconnect link is in a normal operational state. The lane margin may correspond to a voltage margin, and/or a timing margin. The lane margining test may include a parallel margin assessment phase, a serial margin assessment phase, and a fine-tuning margin assessment phase.

The parallel margin assessment phase of the lane margining test can be performed on multiple lanes concurrently to determine a collective baseline offset. The serial margin assessment phase of the lane margining test can be performed sequentially on each lane starting at the collective baseline offset to determine a respective refined baseline offset for each lane beyond which a respective serial margin assessment phase fails for that lane. The fine-tuning margin assessment phase of the lane margining test can be performed sequentially on each lane starting at the respective refined baseline offset for that lane to determine a respective lane margin for that particular lane. The parallel margin assessment phase and the respective serial margin assessment phase for each lane can be performed using a trimmed dwell time that is shorter than a target dwell time used to perform the respective fine-tuning margin assessment phase.

The parallel margin assessment phase may include counting a number of errors that occur across all the lanes during the trimmed dwell time, and increasing a step count across all the lanes when the number of errors across all the lanes during the trimmed dwell time is less than a trimmed error threshold. The collective baseline offset can be determined as the last step count after which the number of errors across all the lanes reaches or exceeds the trimmed error threshold.

The serial margin assessment phase for an individual lane may include, starting at the collective baseline offset, counting a number of errors occurring on the individual lane during the trimmed dwell time, and increasing a step count when the number of errors on the individual lane during the trimmed dwell time is less than a trimmed error threshold. The respective refined baseline offset for the individual lane can be determined as the last step count after which the number of errors of the individual lane reaches or exceeds the trimmed error threshold.

The fine-tuning margin assessment phase for an individual lane may include, starting at the refined baseline offset, counting a number of errors that occur during the target dwell time. When the number of errors on the individual lane at the refined baseline offset during the target dwell time is less than a target error threshold, the fine-tuning margin assessment phase may further include increasing a step count. In this case, the lane margin of the individual lane can be determined as the last step count after which the number of errors on the individual lane during the target dwell time reaches or exceeds than the target error threshold. When the number of errors on the individual lane at the refined baseline offset during the target dwell time is above the target error threshold corresponding to the respective lane, the fine-tuning margin assessment phase may further include decreasing the step count. In this case, the lane margin of the individual lane can be determined as the lowest step count after which the number of errors on the individual lane during the target dwell time reaches or exceeds than the target error threshold.

A peripheral device may include an interconnect to communicate with a host device, and a memory coupled to the interconnect. Applying a lane margining test to the interconnect may include performing a parallel margin assessment phase of the lane margining test on multiple lanes of the interconnect concurrently to determine a collective baseline offset, sequentially performing a serial margin assessment phase of the lane margining test on each lane starting at the collective baseline offset to determine a respective refined baseline offset for each lane beyond which a respective serial margin assessment phase fails for that lane, and sequentially performing a fine-tuning margin assessment phase of the lane margining test on each lane starting at the respective refined baseline offset for that lane to determine a respective lane margin for that lane.

### BRIEF DESCRIPTION OF THE DRAWINGS

The detailed description below makes reference to a few example embodiments that are illustrated in the accompanying drawings. However, it should be understood that the description is equally relevant to various other variations of the embodiments described herein. Such embodiments may utilize objects and/or components other than those illustrated in the drawings. It should also be understood that like reference numerals used in the various figures indicate similar or identical objects.

FIG. 1 illustrates an example eye diagram that is used to describe lane margining for an interconnect link, according to some embodiments.

FIG. 2 illustrates an example sequence of a sequential lane margining assessment process for an interconnect link, according to some embodiments.

FIG. 3 illustrates an example flow for a lane margining test that uses a multi-phase synchronized approach for lane margining, according to some embodiments.

FIG. 4A illustrates an example flow chart for a parallel margin assessment phase, in accordance with some embodiments.

FIG. 4B illustrates an example flow chart for a serial margin assessment phase, in accordance with some embodiments.

FIG. 4C illustrates an example flow chart for a fine-tuning margin assessment phase, in accordance with some embodiments.

FIG. 5 illustrates an example sequence of performing a lane margining test for an interconnect link based on a multi-phase synchronized approach, in accordance with some embodiments.

FIG. 6 illustrates an example integrated circuit (IC) device that can perform a lane margining test on an interconnect link, in accordance with some embodiments.

FIG. 7 illustrates a simplified flow chart for a process to perform a lane margining test for an interconnect link, in accordance with some embodiments.

FIG. 8 illustrates an example architecture of a computing system, in accordance with some embodiments.

FIG. 9 illustrates a computer system usable for implementing one or more embodiments of the present disclosure.

### DETAILED DESCRIPTION

Signal margining can improve the performance of receivers for data transfers using multiple lanes of an interconnect link, since various factors can impact signal quality in an operational state of the interconnect link. For example, manufacturing and environmental variances can cause increase in channel loss, cross talk, and channel discontinuities which may result in poor signal quality due to increased system noise, deteriorated jitter performance and signal eye closure, etc. Furthermore, performance variation and signal integrity degradation become greater as data rates increases. To provide a more robust system, link health can be determined while running actual traffic to evaluate how much signaling margin is available before the system starts experiencing errors, and adjustments can be made to maintain signal integrity.

Generally, the receiver may move its sampling point around within a signal eye to calculate the margin by measuring the signal eye width (e.g., time) and height (e.g., voltage) under normal operating conditions. For example, the receiver may shift left or right with each sampling step to determine at what timing margin a failure occurs, and/or may shift up and down with each sampling step to determine at what voltage margin a failure occurs. The lane margining process can be repeated until the eye width/height becomes acceptable for operating conditions. In some implementations, lane margining can be performed for each lane by moving the sampling location to a new voltage and/or timing setting, and waiting for a certain time period (e.g., also called dwell time) at that voltage and/or timing setting to determine whether the signal quality at that margin is within an acceptable range. For example, the signal quality may not be acceptable at that margin if an error count during the dwell time exceeds a threshold value. If the signal quality is acceptable at that setting, the sampling location may be moved by another step to determine the signal quality at that margin. This process may be repeated for each lane sequentially to assess both the voltage and the timing margins on each lane. However, this sequential lane margining process can be time intensive and costly since the margin assessment for each lane is performed sequentially, which may be further exacerbated as the number of lanes increases for the interconnect link.

Techniques described herein provide a hybrid seek method to assess lane margins for an interconnect link using a multi-phase synchronized approach that may reduce the standard margin testing time significantly (e.g., close to 95%). The multi-phase synchronized approach may include a parallel margin assessment phase, a serial margin assessment phase, and a fine-tuning margin assessment phase, which can be performed while the interconnect link is in a normal operational state to assess voltage margin and/or timing margin for a plurality of lanes of the interconnect link. The parallel margin assessment phase and the serial margin assessment phase may be performed to determine a corresponding baseline using a trimmed dwell time, which is set to be shorter than a target dwell time used by the fine-tuning margin assessment phase.

The parallel margin assessment phase is operable to count a number of errors occurring across all the lanes during the trimmed dwell time, and increase a step count across all the lanes when the number of errors across all the lanes during the trimmed dwell time is less than a trimmed error threshold. The last successful step count after which the number of errors across all the lanes reaches or exceeds the trimmed error threshold may be defined as a collective baseline offset to be used by each lane as a starting baseline to perform the serial margin assessment phase. Thus, as compared to traditional single-lane sequential tests, the parallel margin assessment phase can allow identifying a baseline rapidly with a minimal dwell time. This phase may be particularly advantageous to quickly weed out non-viable settings across all lanes, thus reducing the time taken for preliminarily setting bounds, and increasing the throughput of the lane margining test.

The serial margin assessment phase is operable to refine the margin by serially advancing beyond the collective baseline offset per individual lane using the trimmed dwell time. Similar to the parallel margin assessment phase, the testing may stop if an error occurs, which may optimize the test duration while maintaining high accuracy. For example, the serial margin assessment phase may count a number of errors occurring on the individual lane during the trimmed dwell time, and increase a step count when the number of errors on the individual lane during the trimmed dwell time is less than the trimmed error threshold. The last successful step count after which the number of errors of the individual lane reaches or exceeds the trimmed error threshold, and is below a maximum offset value allowed for that lane, can be used to determine a refined baseline offset for that lane to be used as a baseline for the fine-tuning margin assessment phase. Thus, independently adjusting each lane can allow for detection of lane-specific anomalies that may not have been detected in the parallel margin assessment phase due to the collective nature of that phase.

The fine-tuning margin assessment phase may use refined settings from the serial margin assessment phase as a new starting point, and dynamically adjust the margins based on real-time feedback for each lane. The fine-tuning margin assessment phase may incorporate more detailed assessment criteria to perform the testing to ensure robust margin settings that accommodate various operational conditions and environmental factors. For example, starting at the refined baseline offset for an individual lane, the fine-tuning margin assessment phase may count the number of errors that occur during the target dwell time. The step count can be increased and/or decreased based on the number of errors on the individual lane during the target dwell time being below or above the target error threshold. The lane margin of the individual lane can be determined as the last successful step count after which the number of errors on the individual lane during the target dwell time reaches or exceeds than the target error threshold. Thus, by allowing for margin adjustment in both directions by increasing and decreasing the margins to ensure that each lane's margins are not only optimal but also specific to the individual lane can boost precision of the lane margining test.

In the description provided herein, for the purposes of explanation, specific details are set forth in order to provide a thorough understanding of certain inventive embodiments. However, it will be apparent that various embodiments may be practiced without these specific details. Hence, the figures and description are not intended to be restrictive. Certain words and phrases are used herein based on convenience and such words and phrases should be interpreted in various forms and equivalencies by persons of ordinary skill in the art. For example, the word “bit” as used herein represents a binary value (either a “1” or a “0”) that can be stored in a memory. Furthermore, it should be understood that each of words such as “implementation,” “scenario,” “approach,” “application,” “case” and “configuration” as used herein is an abbreviated version of the phrase “In an example (‘implementation,’ ‘scenario,’ ‘approach,’ ‘application,’ ‘case,’ ‘configuration,’ etc.) in accordance with disclosure.” It should also be understood that the word “example” as used herein is intended to be non-exclusionary and non-limiting in nature.

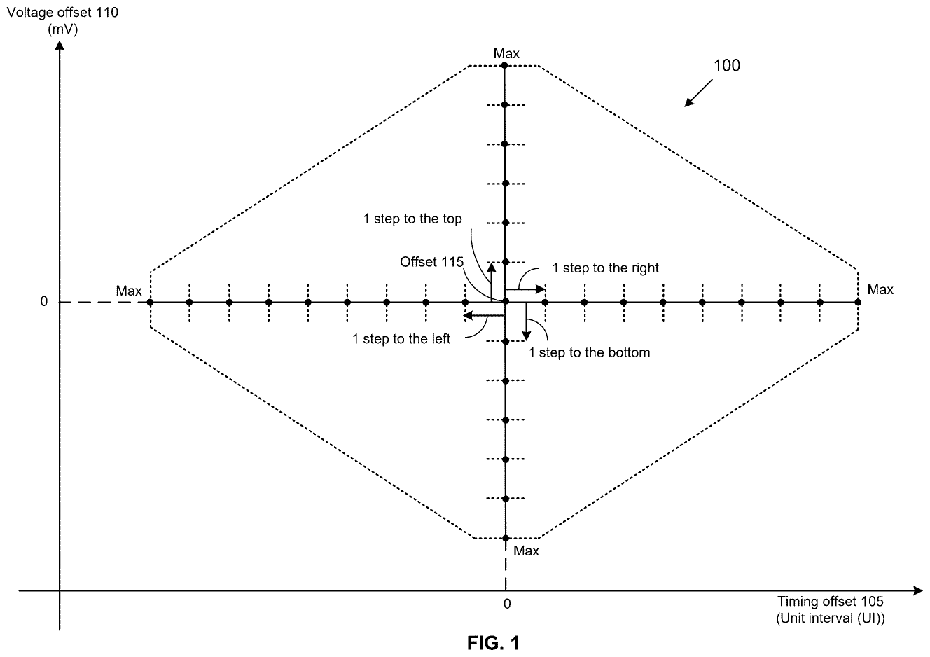

FIG. 1 illustrates an example eye diagram 100 for a signal eye 105 that is used to describe lane margining for an interconnect link. As an example, the interconnect link can be used for communications between a peripheral device (e.g., a storage device, an accelerator device, etc.) and a host device.

The lane margining may be performed at a receiver (e.g., an input port), which can be part of the peripheral device and/or the host device. In some implementations, a physical interface (PHY) of the receiver may determine a minimum eye width margin and a minimum eye height margin by moving a sampling point from a current receiver position to the right or to the left, and/or to the top or to the bottom, in incremental steps for error scanning. A controller can determine lane margins for each lane based on the error count. For example, the sampling point may be moved to a new voltage and/or timing setting, and the signal quality may be checked after waiting for a certain time period (e.g., also called dwell time) at that voltage or timing setting to determine whether the signal quality at that margin is within an acceptable range. As an example, the signal quality may not be acceptable at that margin if an error count during the dwell time exceeds an error threshold value.

As shown in FIG. 1, the eye diagram 100 includes a timing offset 110 in unit intervals (UIs) on an x-axis, and a voltage offset 115 in millivolts (mVs) on a y-axis. In some implementations, lane margining may start at the center of the signal eye 105, represented by an offset 120 having a value 0 for both the timing offset 110 and the voltage offset 115. For example, starting from the offset 120 of the signal eye 105, the eye width may be scanned to the right and to the left, one step at a time, to determine a minimum eye width margin. Similarly, the eye height may be scanned to the top and to the bottom, one step at a time, to determine a minimum eye height margin. The sampling point may stay within a maximum (Max) timing offset and a maximum voltage offset values in either direction as shown in FIG. 1.

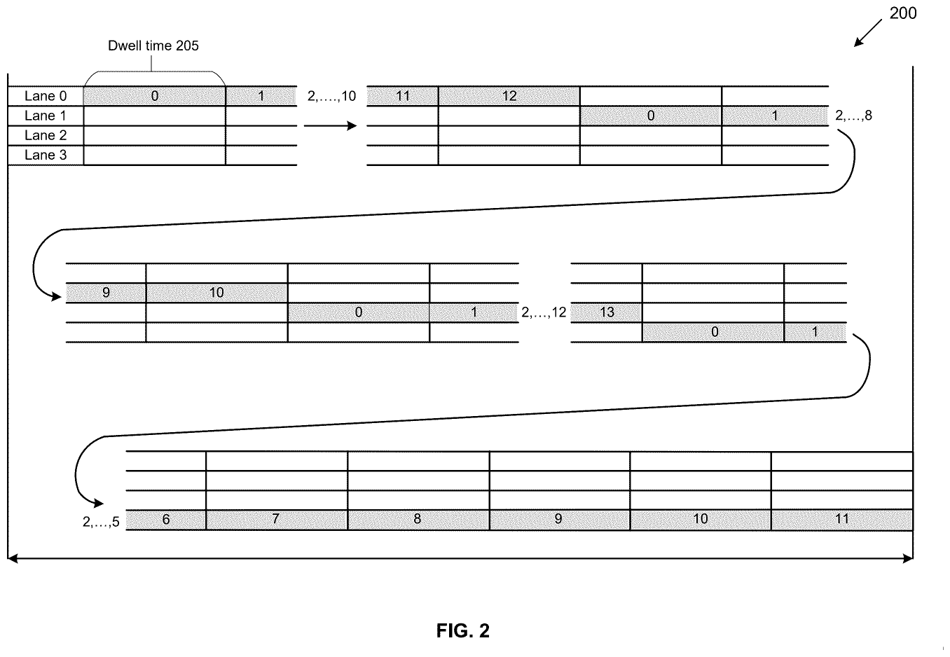

In some implementations, the interconnect link can be a peripheral component interconnect express (PCIe) link, which is widely used for high-speed data transfers between multiple components of a system. A PCIe link is a point-to-point interconnect, which can be used to connect different integrated circuit (IC) components in a system, such as connecting an expansion card (e.g., an accelerator or a graphics processing unit), a storage device (e.g., a solid-state drive), or another peripheral device. The PCIe link generally uses multiple lanes to transfer data over wires using differential signaling. In some implementations, a PCIe controller may obtain margin information from a PHY receiver that includes both voltage and timing offsets, in either direction from the offset 120, while operating in an active or normal operating mode (e.g., L0 link state). The PCIe controller may use the lane margin control and error reporting features to determine the margin in each PCIe lane of the system by evaluating the receiver eye width (the timing offset 110) and the eye height (the voltage offset 115). This is further described with reference to FIG. 2.

FIG. 2 illustrates an example sequence 200 of a sequential lane margining assessment process for four lanes of an interconnect link. As an example, the interconnect link may be a PCIe link that includes a lane 0, a lane 1, a lane 2, and a lane 3. Note that in other examples, the interconnect link may include a higher or fewer number of lanes.

In some implementations, lane margining can be performed sequentially for each of the lanes 0, 1, 2, and 3. For example, sampling point can be moved from a current receiver position to a new voltage or timing setting, and held for a dwell time 205 at that voltage or timing setting to determine whether the signal quality at that margin is within an acceptable range. The signal quality may not be acceptable at that margin if an error count during the dwell time 205 exceeds an error threshold value. If the signal quality is acceptable at that setting, the sampling point can be adjusted by another step to determine the signal quality at that margin. This process can be repeated for each lane sequentially to determine both the voltage and the timing settings having an error count below the error threshold value.

As shown in FIG. 2, the lane margining sequence 200 may start with lane 0. Lane margining for lane 0 can be performed from the current offset of the receiver, e.g., at a step 0 represented by the offset 120 in FIG. 1. As shown in FIG. 2, at step 0, the current timing or voltage setting may be held for duration of the dwell time 205, and the number of errors occurring during the dwell time 205 may be counted to determine the signal quality. If the signal quality is acceptable at that setting, the sampling point can be moved to a step 1 to determine the signal quality at that margin. Referring back to FIG. 1, as an example, the sampling point can be moved one step to the right from the offset 120 to a new value of the timing offset 110, and the signal quality may be determined at the new margin. This process can be repeated for each lane sequentially to determine the voltage or the timing settings having an error count below the error threshold value. Thus, as shown in FIG. 2, the sampling point can be shifted 12 times to the right by incrementing one step at a time, and the signal quality can be checked for each of the corresponding steps 2, . . . , 10, 11, and 12. For the 12^{th} step, the error count may exceed the error threshold value, thus, the margin assessment for lane 0 may end, and the offset value at this point may be determined as the margin on the right for lane 0. A similar process can be performed for the left, upper, and lower margins.

Next the margin assessment for lane 1 can be performed by shifting the sampling point one step at a time and checking the signal quality at each step by comparing the error count occurred during the dwell time 205 with the error threshold value. Error checks can be performed for each corresponding step in a similar manner as lane 0. Similarly, the margin assessments for lane 2 and lane 3 may be performed sequentially by shifting the sampling point one step at a time and checking the signal quality at each step by comparing the error count with the error threshold value. As shown in FIG. 2, the margin assessment for lane 2 may end at an offset value at the 13^{th} step, and for lane 3 may end at an offset value at the 11^{th} step.

As described with reference to FIG. 2, the sequential lane margining process 200 can be time intensive and costly since the margin assessment for each lane is performed sequentially. This is further exacerbated as the number of lanes increases for the interconnect link. Thus, there is a need for an efficient lane margining process which is more time and cost effective than the sequential lane margining process 200 described with reference to FIG. 2.

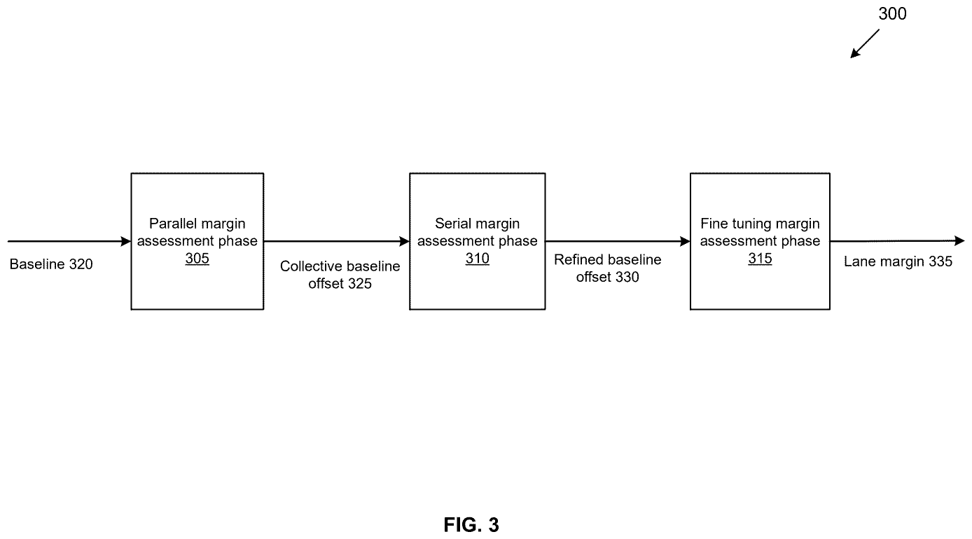

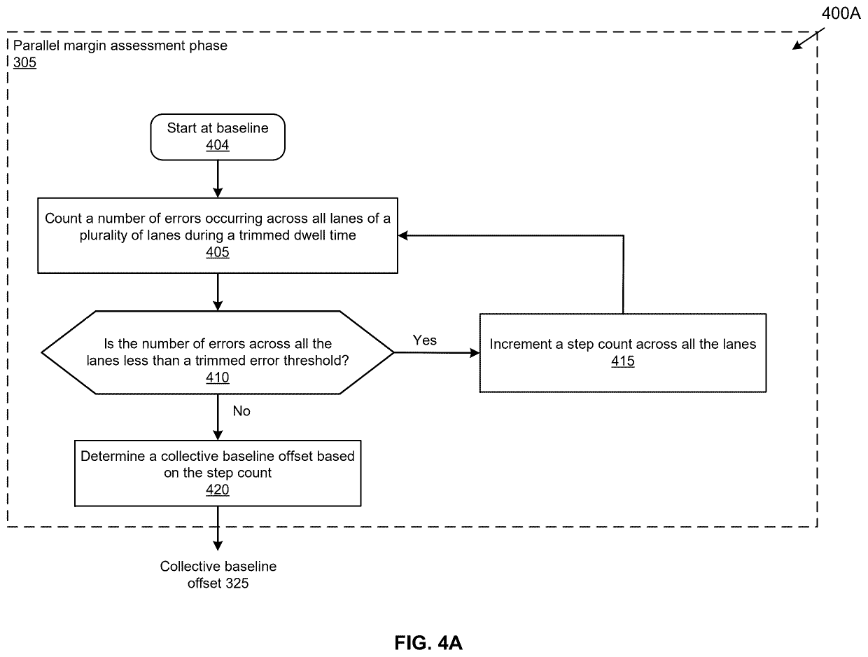

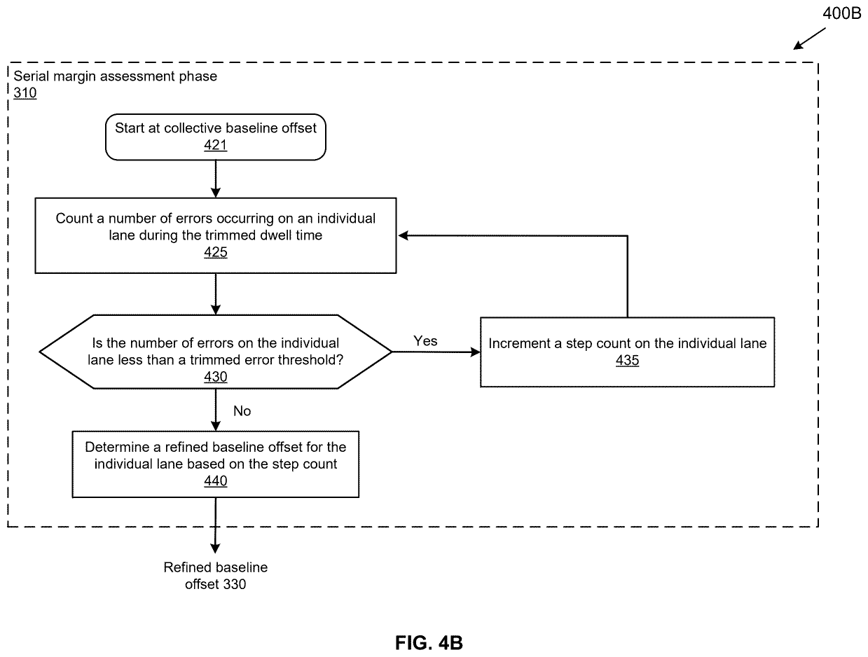

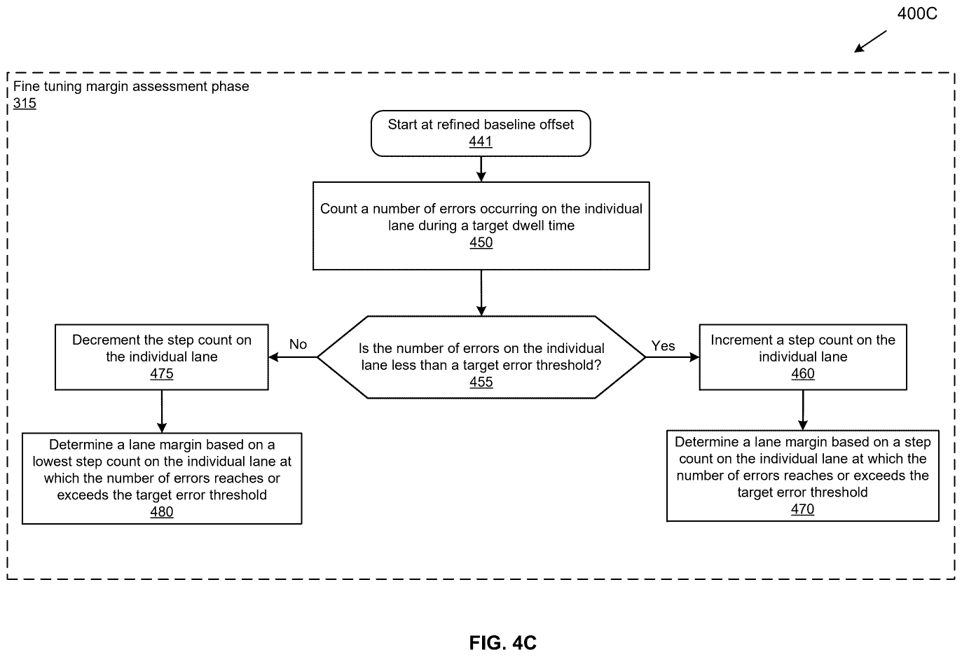

Techniques described herein provide a hybrid seek method that employs a multi-phase methodology to perform a lane margining test that can reduce the lane margining testing time significantly (e.g., about 95%), as compared to sequential testing methods. This method can reduce the testing duration, and also enhance the accuracy and reliability of margin measurements across multiple lanes. This is further described with reference to FIGS. 3, 4A, 4B, and 4C.

FIG. 3 illustrates an example flow for a lane margining test 300 that uses a multi-phase synchronized approach, according to some embodiments. The lane margining test 300 can be applied on an interconnect link having multiple lanes. For example, the interconnect link can be a PCIe link between a host device and a peripheral device, and the number of lanes may include lanes 0, 1, 2, and 3, etc. The lane margining test 300 can be executed by a controller that may be part of the host device or the peripheral device.

In some embodiments, the multi-phases of the lane margining test 300 may include a parallel margin assessment phase 305, a serial margin assessment phase 310, and a fine-tuning margin assessment phase 315. The lane margining test 300 can be performed while the interconnect link is in an active or normal operational state, e.g., L0 state for the PCIe link. In other words, the lane margining test 300 can be performed while the link is in the trained and synchronized state. Lane margin may correspond to a voltage margin represented by the volage offset 115, and/or a timing margin represented by the timing offset 110 for the signal eye 105, described with reference to FIG. 1. The parallel margin assessment phase 305 and the serial margin assessment phase 310 can be performed using a trimmed dwell time that is shorter than a target dwell time used to perform the fine tuning margin assessment phase 315.

In the parallel margin assessment phase 305, all the lanes can be tested concurrently using a common baseline offset 320 for margin assessments over the trimmed dwell time. For example, the common baseline offset 320 can be the offset 120 representing the center of the signal eye 105. The parallel margin assessment phase 305 may include counting the number of errors occurring across all the lanes during the trimmed dwell time, and increasing a step count across all the lanes when the number of errors across all the lanes during the trimmed dwell time is less than a trimmed error threshold. As compared to traditional single-lane sequential tests, the parallel margin assessment phase 305 can allow identifying a baseline rapidly with a minimal dwell time. For example, the last successful step count after which the number of errors across all the lanes reaches or exceeds the trimmed error threshold can be defined as a collective baseline offset 325. Thus, parallel testing during this phase may imply that if one lane fails at a certain offset, all lanes may cease further testing at this and higher offsets. The last successful offset can be designated as the collective baseline offset 325 for all the lanes for the subsequent phase. This strategy can be particularly advantageous to quickly weed out non-viable settings across all lanes, thus reducing the time taken for preliminarily setting bounds. The parallel margin assessment phase 305 is described in detail with reference to FIG. 4A.

The serial margin assessment phase 310 may start once a collective baseline across the lanes has been established by the parallel margin assessment phase 305. The serial margin assessment phase 310 may refine the margin by serially advancing beyond the collective baseline offset 325 per individual lane using the trimmed dwell time. Similar to the parallel margin assessment phase 305, the testing may stop if an error occurs, which may optimize the test duration while maintaining high accuracy. For example, the serial margin assessment phase 310 may include counting a number of errors occurring on the individual lane during the trimmed dwell time, and increasing a step count when the number of errors on the individual lane during the trimmed dwell time is less than the trimmed error threshold. Each lane may be independently adjusted, allowing for detection and correction of lane-specific anomalies that may not have been accounted for due to the collective nature of the parallel margin assessment phase 305. The serial margin assessment phase 310 can provide a refined baseline offset 330 for each lane based on the last successful step count after which the number of errors of the individual lane reaches or exceeds the trimmed error threshold, and a maximum offset value allowed for that lane. The serial margin assessment phase 310 is described in detail with reference to FIG. 4B.

The fine-tuning margin assessment phase 315 may use the refined settings from the serial margin assessment phase 310 as a new starting point and dynamically adjust the margins based on real-time feedback for each lane. The fine-tuning margin assessment phase 315 may incorporate more detailed assessment criteria to perform the testing to ensure robust margin settings that accommodate various operational conditions and environmental factors. For example, the fine-tuning margin assessment phase 315 may use a target dwell time which is longer than the trimmed dwell time used by the parallel margin assessment phase 305 and the serial margin assessment phase 310, and a target error threshold that is more precise than the trimmed error threshold. This adaptive methodology may allow for margin adjustment in both directions by increasing and decreasing the margins to ensure that each lane's margins are accurately determined.

The fine-tuning margin assessment phase 315 for an individual lane may include, starting at the refined baseline offset 330, counting the number of errors that occur during the target dwell time. If the number of errors on the individual lane during the target dwell time is below the target error threshold, the fine-tuning margin assessment phase 315 may continue increasing the step count while the number of errors on the individual lane stays below the target error threshold. In this case, the lane margin of the individual lane can be determined as the last successful step count after which the number of errors on the individual lane during the target dwell time reaches or exceeds than the target error threshold. If the number of errors on the individual lane during the target dwell time is above the target error threshold, the fine-tuning margin assessment phase 315 may continue decreasing the step count while the number of errors on the individual lane stays above the target error threshold. In this case, the lane margin of the individual lane may be determined as the lowest step count after which the number of errors on the individual lane during the target dwell time reaches or exceeds than the target error threshold. The fine-tuning margin assessment phase 315 is described in detail with reference to FIG. 4C.

FIG. 4A illustrates an example flow chart 400A for the parallel margin assessment phase 305, in accordance with some embodiments.

At step 405, the parallel margin assessment phase 305 may start at a baseline initially to count the number of errors occurring across all the lanes during the trimmed dwell time. In some embodiments, a “step margin” command may be issued concurrently across all the lanes 0, 1, 2, and 3 that includes the trimmed dwell time, and an offset value. In some implementations, the step margin command may be issued to each lane in parallel by writing to a corresponding command register with the trimmed dwell time, and the offset value. The offset value may represent a step count relative to the initial receiver position, e.g., the offset 120 in FIG. 1. For example, the parallel margin assessment phase 305 may start at the baseline 320 representing the step count of 0 at the offset 120. The PHY of the receiver for each lane may adjust the timing or the voltage based on the offset value and update an error count register over the duration of the trimmed dwell time.

At step 410, the parallel margin assessment phase 305 may count a number of errors occurring across all lanes of a plurality of lanes during a trimmed dwell time. For example, errors occurring in each lane can be accumulated in the error count register, and the register can be read in response to the “step margin” command. Thus, the parallel margin assessment phase 305 may track the error count collectively for all the lanes 0, 1, 2, and 3.

At step 415, the parallel margin assessment phase 305 may determine whether the number of errors across all the lanes is less than a trimmed error threshold. For example, the parallel margin assessment phase 305 may compare the total number of errors across the lanes 0, 1, 2, and 3 with the trimmed error threshold.

At step 420, the parallel margin assessment phase 305 may increment a step count across all the lanes if the number of errors across all the lanes is less than the trimmed error threshold. For example, another “step margin” command may be issued concurrently across all the lanes 0, 1, 2, and 3 to write the corresponding command register with the trimmed dwell time, and a new offset value representing a step count of 1. The parallel margin assessment phase 305 may count the number of errors occurring across the lanes 0, 1, 2, and 3 during the trimmed dwell time in the step 410, and determine whether the number of errors across all the lanes is less than the trimmed error threshold in the step 415. Thus, the steps 410, 415, and 420 may be repeated for each new offset value based on the incremented step count while the number of errors across the lanes 0, 1, 2, and 3 stay below the trimmed error threshold.

At step 425, the parallel margin assessment phase 305 may determine a collective baseline offset based on the step count when the number of errors across the lanes 0, 1, 2, and 3 reaches or exceeds the trimmed error threshold. The collective baseline offset 325 may be the last successful offset or the step count at which the number of errors across all the lanes is less than the trimmed error threshold. For example, referring back to FIG. 1, if the number of errors across the lanes 0, 1, 2, and 3 reaches or exceeds the trimmed error threshold when the step count is 4, the collective baseline offset 325 may correspond to the step count of 3 for which the number of errors across all the lanes is less than the trimmed error threshold.

FIG. 4B illustrates an example flow chart 400B for the serial margin assessment phase 310, in accordance with some embodiments. The serial margin assessment phase 310 can be performed on each lane sequentially, e.g., starting with the lane 0.

At step 430, the serial margin assessment phase 310 may start at the collective baseline offset for an individual lane. In some embodiments, a “step margin” command may be issued to lane 0 that includes the trimmed dwell time, and the collective baseline offset by writing to a command register corresponding to lane 0. The same collective baseline offset from the last successful step count for the parallel margin assessment phase 305 can be used for all the lanes 0, 1, 2, and 3. The PHY of the receiver for lane 0 may adjust the timing and/or the voltage based on the collective baseline offset 325.

At step 435, the serial margin assessment phase 310 may count the number of errors occurring on an individual lane during the trimmed dwell time. For example, an error count register counting errors for lane 0 may be read in response to the “step margin” command.

At step 440, the serial margin assessment phase 310 may determine whether the number of errors on the individual lane is less than a trimmed error threshold. For example, the serial margin assessment phase 310 may compare the number of errors on lane 0 with the trimmed error threshold.

At step 445, the serial margin assessment phase 310 may increment a step count on the individual lane if the number of errors on the individual lane is less than the trimmed error threshold. For example, another “step margin” command may be issued on lane 0 to write the corresponding command register with the trimmed dwell time, and a new offset value. The serial margin assessment phase 310 may count the number of errors occurring on lane 0 during the trimmed dwell time in the step 440, and determine whether the number of errors on lane 0 is less than the trimmed error threshold in the step 440. Thus, the steps 435, 440, and 445 may be repeated while the number of errors on lane 0 stays below the trimmed error threshold for each new offset value based on the incremented step count, and when each new offset value is less than a maximum offset value allowed for lane 0.

At step 450, the serial margin assessment phase 310 may determine a refined baseline offset for the individual lane based on the step count and a maximum offset value when the number of errors on the individual lane reaches or exceeds the trimmed error threshold. When the number of errors on the individual lane reaches or exceeds the trimmed error threshold, the last successful offset at which the number of errors on lane 0 is less than the trimmed error threshold, and which is below the maximum offset value allowed for lane 0, is determined as the refined baseline offset 330.

Similarly, the steps 430, 435, 440, 445, and 450 may be performed for each lane of the multiple lanes of the interconnect link. For example, a respective refined baseline offset 330 may be determined for each of the lanes 1, 2, and 3 starting with the same collective baseline offset 325. Thus, the serial margin assessment phase 310 may allow adjusting each lane independently by detecting and correcting anomalies specific to each lane.

FIG. 4C illustrates an example flow chart 400C for the fine-tuning margin assessment phase 315, in accordance with some embodiments. The fine-tuning margin assessment phase 315 can be performed on each lane sequentially, e.g., starting with lane 0, after performing the serial margin assessment phase 310 sequentially.

At step 460, the fine-tuning margin assessment phase 315 may start at a refined baseline offset for an individual lane. In some embodiments, a “step margin” command can be issued to lane 0 that includes a target dwell time, and the refined baseline offset by writing to a command register corresponding to lane 0. The refined baseline offset may be the refined baseline offset 330 for lane 0 that includes the last successful step count for lane 0 for the serial margin assessment phase 310. The PHY of the receiver for lane 0 may adjust the timing and/or the voltage based on the refined baseline offset 330.

At step 465, the fine-tuning margin assessment phase 315 may count the number of errors occurring on the individual lane during the target dwell time. For example, an error count register for lane 0 may be read in response to the “step margin” command.

At step 470, the fine-tuning margin assessment phase 315 may determine whether the number of errors on the individual lane is less than a target error threshold. For example, the fine-tuning margin assessment phase 315 may compare the number of errors on lane 0 with the target error threshold.

At step 475, the fine-tuning margin assessment phase 315 may increment a step count on the individual lane if the number of errors on the individual lane is less than the target error threshold. For example, another “step margin” command may be issued on lane 0 to write the corresponding command register with the target dwell time, and a new offset value for the incremented step count.

At step 480, the fine-tuning margin assessment phase 315 may determine a lane margin based on a step count on the individual lane at which the number of errors reaches or exceeds the target error threshold. For example, the fine-tuning margin assessment phase 315 may continue incrementing the step count on lane 0 while the number of errors on lane 0 stays below the target error threshold. The lane margin can be determined as the last successful step count for which the number of errors on lane 0 stays below the target error threshold.

At step 485, the fine-tuning margin assessment phase 315 may decrement a step count on the individual lane if the number of errors on the individual lane reaches or exceeds the target error threshold in the step 470. For example, a “step margin” command may be issued on lane 0 to write the corresponding command register with the target dwell time, and a previous offset value for the decremented step count.

At step 490, the fine-tuning margin assessment phase 315 may determine a lane margin based on the lowest step count on the individual lane at which the number of errors reaches or exceeds the target error threshold. For example, the fine-tuning margin assessment phase 315 may continue decrementing the step count on lane 0 while the number of errors on lane 0 stays below the target error threshold. The lane margin can be determined as the last successful step count for which the number of errors on lane 0 stays below the target error threshold.

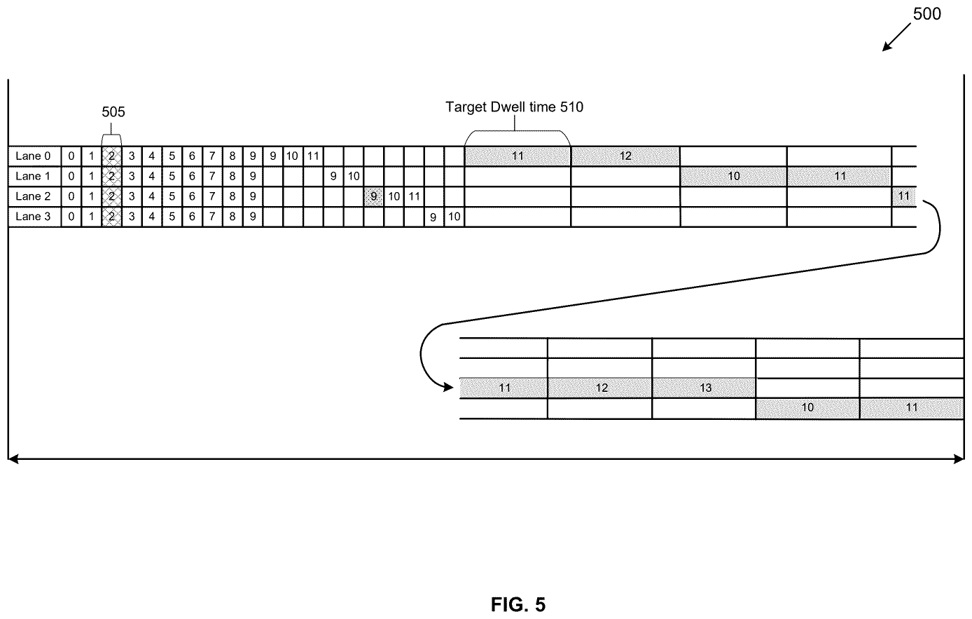

FIG. 5 illustrates an example sequence 500 of performing a lane margining test on four lanes of an interconnect link based on a multi-phase synchronized approach, according to some embodiments of the disclosure. As an example, the lane margining test 300 can be performed on the PCIe link comprising the lanes 0, 1, 2, and 3. Note that in other examples, the interconnect link may include higher or fewer number of lanes.

As shown in FIG. 5, the parallel margin assessment phase 305 of the lane margining test 300 may be performed to test all the lanes 0, 1, 2, and 3 concurrently using the common baseline offset 320 for margin assessments over a trimmed dwell time 505. Initially, the step count for each lane may be 0 corresponding to the offset 120 in FIG. 1. A number of errors occurring across all the lanes 0, 1, 2, and 3 during the trimmed dwell time 505 may be counted, and the step count across all the lanes 0, 1, 2, and 3 may continue to be incremented while the number of errors across all the lanes 0, 1, 2, and 3 during the trimmed dwell time 505 stays below the trimmed error threshold. As shown in FIG. 5, the step count may be incremented from 0 to 1, 2, 3, 4, 5, 6, 7, 8, and 9 due to the number of errors across all the lanes 0, 1, 2, and 3 being less than the trimmed error threshold during the trimmed dwell time 505 for each incremented step count. When the step count is incremented to 10, the number of errors across all the lanes 0, 1, 2, and 3 during the trimmed dwell time 505 may reach or exceed the trimmed error threshold. Thus, the step count 9 may correspond to the last successful offset at which the number of errors across all the lanes 0, 1, 2, and 3 is less than the trimmed error threshold, and is set as the collective baseline offset 325 to be used as the baseline for performing the serial margin assessment phase 310 on each individual lane.

The serial margin assessment phase 310 may start performing the lane margining test on lane 0 using the step count 9 as the collective baseline offset 325. The number of errors occurring on lane 0 during the trimmed dwell time 505 may be counted, and the step count on lane 0 may continue to be incremented while the number of errors on lane 0 during the trimmed dwell time 505 stays below the trimmed error threshold. As shown in FIG. 5, the step count for lane 0 may be incremented from 9 to 10 and 11 due to the number of errors on lane 0 being less than the trimmed error threshold during the trimmed dwell time 505 for each incremented step count. When the step count is incremented to 12, the number of errors on lane 0 during the trimmed dwell time 505 may reach or exceed the trimmed error threshold. Thus, the step count 11 may correspond to the last successful offset at which the number of errors on lane 0 is less than the trimmed error threshold, and is the refined baseline offset 330 to be used as the baseline for performing the fine-tuning margin assessment phase 315 on lane 0. It should be noted that in some implementations, the trimmed error threshold used in the serial margin assessment phase 310 can be different than the trimmed error threshold used in the parallel margin assessment phase 305.

Similarly, the serial margin assessment phase 310 may perform the lane margining test on lane 1, lane 2, and lane 3, sequentially, starting with the step count 9 as the collective baseline offset 325, and determine a respective refined baseline offset 330 for each lane. As shown in FIG. 5, the serial margin assessment phase 310 can determine the step count 10 as the refined baseline offset 330 to be used for performing the fine-tuning margin assessment phase 315 on lane 1. Next, the serial margin assessment phase 310 can determine the step count 11 as the refined baseline offset 330 to be used for performing the fine-tuning margin assessment phase 315 on lane 2. Lastly, the serial margin assessment phase 310 can determine the step count 10 as the refined baseline offset 330 to be used for performing the fine-tuning margin assessment phase 315 on lane 3.

Once the respective refined baseline offsets 330 have been determined for each of the lanes 0, 1, 2, and 3 by the serial margin assessment phase 310, the fine tuning margin assessment phase 315 can be performed on each of the lanes 0, 1, 2, and 3 sequentially starting with the respective refined baseline offsets 330 to determine a respective lane margin using a target dwell time 510.

As shown in FIG. 5, the fine-tuning margin assessment phase 315 may start the lane margining test on lane 0 with the step count 11 as the refined baseline offset 330. The number of errors occurring on lane 0 during the target dwell time 510 can be counted. If the number of errors on lane 0 during the target dwell time 510 is below the target error threshold, the step count on lane 0 may continue to be incremented until the error count reaches or exceeds the target error threshold. If the number of errors on lane 0 during the target dwell time 510 is above the target error threshold, the step count on lane 0 may continue to be decremented until the error count is below the target error threshold. The lane margin for lane 0 may be determined as the step count 12 for which the number of errors on lane 0 stays below the target error threshold.

Next, the fine-tuning margin assessment phase 315 may start the lane margining test on lane 1 with the step count 10 as the refined baseline offset 330, and determine a lane margin for lane 1 based on a step count 11 as the last successful step count for which the number of errors on lane 1 stays below the target error threshold. Next, the fine-tuning margin assessment phase 315 may start the lane margining test on lane 2 with the step count 11 as the refined baseline offset 330, and determine a lane margin for lane 2 based on a step count 13 as the last successful step count for which the number of errors on lane 2 stays below the target error threshold. Lastly, the fine-tuning margin assessment phase 315 may start the lane margining test on lane 3 with the step count 10 as the refined baseline offset 330, and determine a lane margin for lane 3 based on a step count 11 as the last successful step count for which the number of errors on lane 3 stays below the target error threshold.

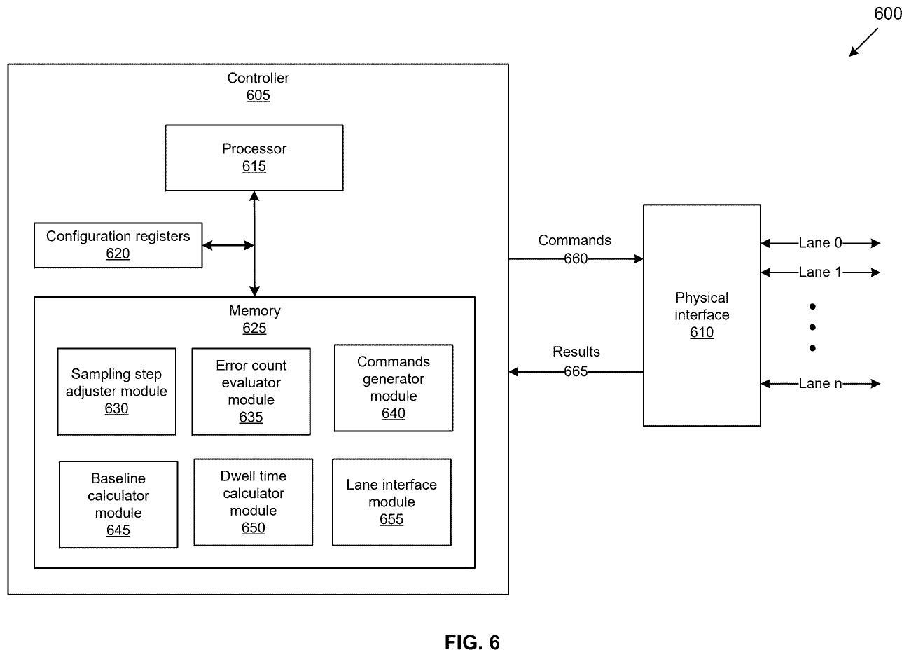

FIG. 6 illustrates an example integrated circuit (IC) device 600 that can perform a lane margining test on an interconnect link 640, in accordance with some embodiments. As an example, the interconnect link 640 may be used to connect a peripheral device and a host device, and the IC device 600 may be part of the peripheral device and/or the host device.

The interconnect link 640 may include N number of lanes comprising a lane 0, a lane 1, a lane 2, and a lane n. In some embodiments, the interconnect link 640 may be a PCIe link comprising lanes 0, 1, 2, and 3 (e.g., N is 4). The IC device 600 may include a controller 605 and a physical interface (PHY) 610 coupled to the interconnect link 640. The controller 605 may include a processor 610 coupled to configuration registers 625 and memory 615. As an example, the controller 605 may be a PCIe controller, which may include additional components that are not described here for ease of discussion.

The configuration registers 625 may be used to store different configuration values for each of the N lanes for lane margining process. For example, the configuration registers 625 may store the trimmed dwell time 505 used for the “step margin” commands to increase the step counts for the parallel margin assessment phase 305 and the serial margin assessment phase 310. The configuration registers 625 may also store the target dwell time 510 used for the “step margin” commands to increase or decrease the step counts for the fine-tuning margin assessment phase 315. The configuration registers 625 may also store the trimmed error threshold, and target error thresholds to be used by the lane margining tests for comparing with the error counts.

The memory 615 may include a lane margining test module 620, which may be operable to determine a lane margin for each of the lanes of the interconnect link 640. For example, the lane margining test module 620 may be operable to perform a parallel margin assessment phase of a lane margining test on the plurality of lanes concurrently to determine a collective baseline offset. The lane margining test module 620 may be further operable to sequentially perform a serial margin assessment phase of the lane margining test on each lane starting at the collective baseline offset to determine a respective refined baseline offset for each lane beyond which a respective serial margin assessment phase fails for that lane. The lane margining test module 620 may be further operable to sequentially perform a fine-tuning margin assessment phase of the lane margining test on each lane starting at the respective refined baseline offset for that lane to determine a respective lane margin for that lane. As an example, the lane margining test module 620 may perform the lane margining test 300 comprising the parallel margin assessment phase 305, serial margin assessment phase 310, and the fine-tuning margin assessment phase 315 to determine the respective lane margin 335 for each of the N lanes.

The lane margining test module 620 may be further operable to issue commands 630 to the PHY 610 and receive responses 635 from the PHY 610. For example, the commands 630 may include “step margin” commands to increase or decrease the step count as described with reference to FIGS. 3, 4A, 4B, and 4C. The commands 630 may also include reading the error counts that occur during the trimmed dwell time 505 and the target dwell time 510. The PHY 610 may be operable to adjust the voltage or timing of the signal based on the “step margin” commands 630, and track the error counts accordingly. Note that other implementations are possible to adjust the timing/voltage offsets and receive the error counts without deviating from the scope of the disclosure.

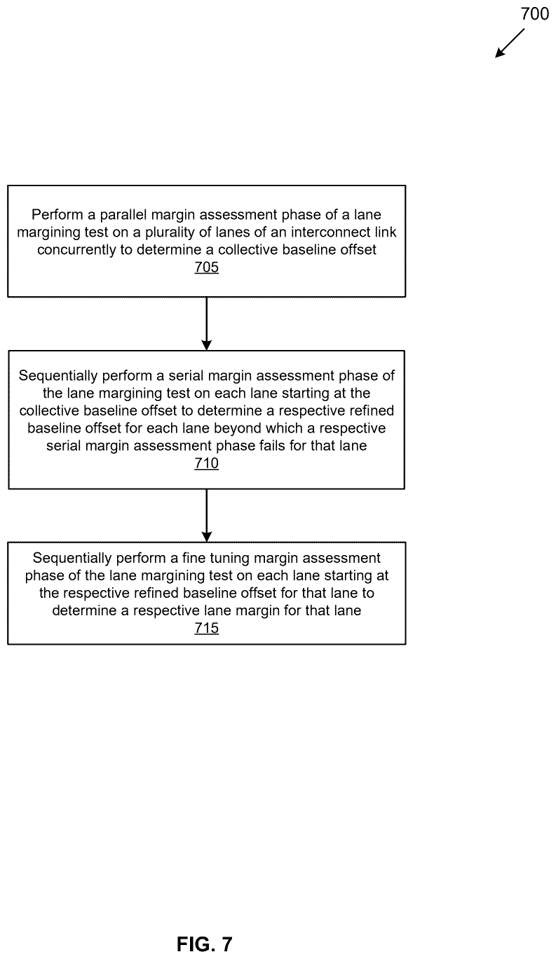

FIG. 7 illustrates a simplified flow chart 700 for a process to perform a lane margining test for a plurality of lanes of an interconnect link, in accordance with some embodiments of the disclosure. The interconnect link 640 can be a PCIe link between a peripheral device and a host device. For example, the process may be executed by the peripheral device or the host device to perform the lane margining test 300 on a PCIe link using the lane margining module 620. In some implementations, the peripheral device can be a storage device having a memory that can be written by the host device to store data for various applications.

The process can include, at step 705, performing a parallel margin assessment phase of the lane margining test on the plurality of lanes concurrently to determine a collective baseline offset. The parallel margin assessment phase may include counting a number of errors occurring across all the lanes during the trimmed dwell time, and increasing a step count across all the lanes when the number of errors across all the lanes during the trimmed dwell time is less than a trimmed error threshold. The collective baseline offset may be determined as the last step count after which the number of errors across all the lanes reaches or exceeds the trimmed error threshold. For example, the parallel margin assessment phase 305 of the lane margining test 300 can be performed on the lanes 0, 1, 2, and 3 of the interconnect link 640 starting with the baseline 320 representing the step count 0. As described with reference to FIG. 5, the number of errors occurring across lanes 0, 1, 2, and 3 during the trimmed dwell time 505 for each of the step counts 0, 1, 2, . . . , 8, and 9 may be less than the trimmed error threshold 505, but for the step count 10 may be more than the trimmed error threshold 505. Thus, the collective baseline offset 325 may be determined as the step count 9 after which the number of errors across the lanes 0, 1, 2, and 3 reaches or exceeds the trimmed error threshold.

At step 710, a serial margin assessment phase of the lane margining test can be sequentially performed on each lane starting at the collective baseline offset to determine a respective refined baseline offset for each lane beyond which a respective serial margin assessment phase fails for that lane. The serial margin assessment phase for an individual lane includes, starting at the collective baseline offset, counting the number of errors occurring on the individual lane during the trimmed dwell time, and increasing a step count when the number of errors on the individual lane during the trimmed dwell time is less than a trimmed error threshold. The respective refined baseline offset for the individual lane is determined as a last step count after which the number of errors of the individual lane reaches or exceeds the trimmed error threshold. For example, the serial margin assessment phase 310 of the lane margining test 300 may be performed sequentially on each of the lanes 0, 1, 2, and 3 starting at the collective baseline offset 325 representing the step count 9.

As described with reference to FIG. 5, the number of errors occurring across lane 0 during the trimmed dwell time 505 for each of the step counts 9, 10, and 11 may be less than the trimmed error threshold, but for the step count 12 may be more than the trimmed error threshold. Thus, the refined baseline offset for lane 0 may be determined as the step count 11 after which the number of errors on lane 0 reaches or exceeds the trimmed error threshold. Similarly, the refined baseline offset for lane 1 may be determined as the step count 10 after which the number of errors on lane 1 reaches or exceeds the trimmed error threshold, the refined baseline offset for lane 2 may be determined as the step count 11 after which the number of errors on lane 2 reaches or exceeds the trimmed error threshold, and the refined baseline offset for lane 3 may be determined as the step count 10 after which the number of errors on lane 3 reaches or exceeds the trimmed error threshold.

At step 715, a fine-tuning margin assessment phase of the lane margining test can be sequentially performed on each lane starting at the respective refined baseline offset for that lane to determine a respective lane margin for that lane. The fine-tuning margin assessment phase for an individual lane includes, starting at the refined baseline offset, counting the number of errors that occur during the target dwell time, and increasing a step count when the number of errors on the individual lane at the refined baseline offset during the target dwell time is less than a target error threshold. In this case, the lane margin of the individual lane is determined as a last step count after which the number of errors on the individual lane during the target dwell time reaches or exceeds than the target error threshold. The fine-tuning margin assessment phase further includes decreasing the step count when the number of errors on the individual lane at the refined baseline offset during the target dwell time is above the target error threshold corresponding to the respective lane. In this case, the lane margin of the individual lane is determined as a lowest step count after which the number of errors on the individual lane during the target dwell time reaches or exceeds than the target error threshold.

For example, the fine-tuning assessment phase 315 of the lane margining test 300 can be performed sequentially on each of the lanes 0, 1, 2, and 3 starting at the step counts 11, 10, 11, and 10, respectively. As described with reference to FIG. 5, the number of errors occurring across lane 0 during the target dwell time 510 for each of the step counts 11 and 12 may be less than the target error threshold, but for the step count 13 may be more than the target error threshold. Thus, the lane margin for lane 0 can be determined as the step count 12 after which the number of errors on lane 0 reaches or exceeds the target error threshold. Similarly, the lane margin for lane 1 can be determined as the step count 11 after which the number of errors on lane 1 reaches or exceeds the target error threshold, the lane margin for lane 2 can be determined as the step count 13 after which the number of errors on lane 2 reaches or exceeds the target error threshold, and the lane margin for lane 3 can be determined as the step count 11 after which the number of errors on lane 3 reaches or exceeds the target error threshold.

Thus, the techniques described herein can be used to assess lane margins for an interconnect link using a multi-phase synchronized approach that may reduce the standard margin testing time significantly (e.g., close to 95%) by integrating three operational phases: the parallel margin assessment phase, the serial margin assessment phase, and the fine-tuning margin assessment phase. This approach can reduce the testing duration and also enhance the accuracy and reliability of margin measurements across multiple lanes.

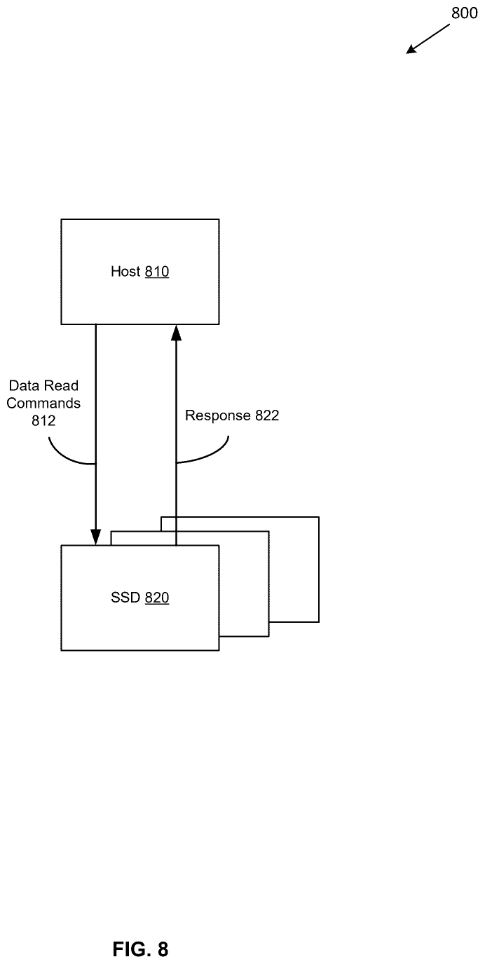

FIG. 8 illustrates an example architecture of a computing system 800, in accordance with certain embodiments of the present disclosure. In an example, the computer system 800 includes a host 810 and one or more peripheral devices 820. An example peripheral device 820 can be a solid-state drive (SSD). For example, the host 810 may store data on behalf of clients in the SSDs.

The host 810 can receive a request from a client for the client's data stored in the SSDs 820. In response, the host sends data read commands 812 to the SSDs 820 as applicable. Each of the SSDs 820 processes the received data read command and sends a response 822 to the host 810 upon completion of the processing. The response 822 can include the read data and/or a decoding failure. In an example, each of the SSDs includes at least one ECC decoder and/or a BF decoder.

Processing the data read command and sending the response 822 includes decoding by the ECC decoder(s) the codewords stored in the SSD to output the read data and/or the decoding failure. Some of the codewords may be decoded by a BF decoder, or some other decoding technique applied to circulant submatrices.

Generally, an SSD can be a storage device that stores data persistently or caches data temporarily in nonvolatile semiconductor memory and is intended for use in storage systems, servers (e.g., within datacenters), and direct-attached storage (DAS) devices. A growing number of applications need high data throughput and low transaction latency, and SSDs are used as a viable storage solution to increase performance, efficiency, and reliability. SSDs generally use NAND flash memory and deliver higher performance and consume less power than spinning hard-disk drives (HDDs). NAND Flash memory has a number of inherent issues associated with it, the two most important include a finite life expectancy as NAND Flash cells wear out during repeated writes, and a naturally occurring error rate. SSDs can be designed and manufactured according to a set of industry standards that define particular performance specifications, including latency specifications, to support heavier write workloads, more extreme environmental conditions and recovery from a higher bit error rate (BER) than a client SSD (e.g., personal computers, laptops, and tablet computers).

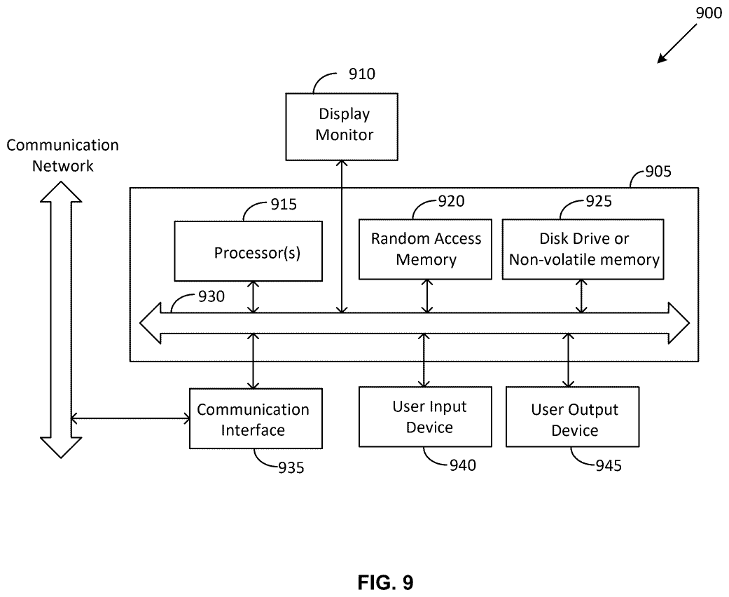

FIG. 9 illustrates a computer system 900 usable for implementing one or more embodiments of the present disclosure. FIG. 9 is merely an example and does not limit the scope of the disclosure as recited in the claims. As shown in FIG. 9, the computer system 900 may include a display monitor 910, a computer 905, a user output device 945, a user input device 940, a communications interface 935, and may further include other computer hardware or accessories.

The computer 905 may include one or more processors such as, for example, the processor 915 that is configured to communicate with a number of peripheral devices via a bus subsystem 930. Some example peripheral devices may include the user output device 945, the user input device 940, and the communications interface 935. The computer 905 may further include a storage subsystem that includes a random-access memory (RAM) 920 and a disk drive 925 or other forms of non-volatile memory.

The user input device 940 can be any of various types of devices and mechanisms for inputting information to the computer 905 such as, for example, a keyboard, a keypad, a touch screen incorporated into the display, and audio input devices (such as voice recognition systems, microphones, and other types of audio input devices). In various embodiments, the user input device 940 is typically embodied as a computer mouse, a trackball, a track pad, a joystick, a wireless remote, a drawing tablet, a voice command system, an eye tracking system, and the like. The user input device 940 typically allows a user to select objects, icons, text and the like that appear on the monitor 910 via a command such as a click of a button or the like.

The user output device 945 can be any of various types of devices and mechanisms for outputting information from the computer 905 such as, for example, a display (e.g., the display monitor 910), non-visual displays such as audio output devices, etc.

The communications interface 935 provides an interface to a communication network. The communications interface 935 may serve as an interface for receiving data from and transmitting data to other systems. Embodiments of the communications interface 935 typically include an Ethernet card, a modem (telephone, satellite, cable, ISDN), (asynchronous) digital subscriber line (DSL) unit, FireWire interface, USB interface, and the like. In an example implementation, the communications interface 935 may be coupled to a computer network, to a FireWire bus, or the like. In other example implementations, the communications interfaces 935 may be physically integrated on the motherboard of the computer 905, and may include a software program, such as soft DSL, or the like.

In various embodiments, the computer system 900 may also include software that enables communications over a network such as the HTTP, TCP/IP, RTP/RTSP protocols, and the like. In alternative embodiments of the present disclosure, other communications software and transfer protocols may also be used, for example IPX, UDP or the like.

The RAM 920 and the disk drive 925 are examples of non-transitory computer-readable media configured to store computer-executable instructions for performing operations associated with various embodiments of the present disclosure, including executable computer code, human readable code, or the like. Other types of computer-readable storage media include floppy disks, removable hard disks, optical storage media such as CD-ROMS, DVDs and bar codes, semiconductor memories such as flash memories, non-transitory read-only-memories (ROMS), battery-backed volatile memories, networked storage devices, and the like. The RAM 920 and the disk drive 925 may be configured to store the basic programming and data constructs that provide the functionality of the present disclosure.

Software code modules and instructions that provide the functionality of the present disclosure may be stored in the RAM 920 and the disk drive 925. These software modules may be executed by the processor 915. The RAM 920 and the disk drive 925 may also provide a repository for storing data used in accordance with the present disclosure.

The RAM 920 and the disk drive 925 may include a number of memories such as a main random-access memory (RAM) for storage of instructions and data during program execution and a read-only memory (ROM) in which fixed non-transitory instructions are stored. The RAM 920 and the disk drive 925 may include a file storage subsystem providing persistent (non-volatile) storage for program and data files. The RAM 920 and the disk drive 925 may also include removable storage systems, such as removable flash memory.

The bus subsystem 930 provides a mechanism for letting the various components and subsystems of the computer 905 communicate with each other as intended. Although the bus subsystem 930 is shown schematically as a single bus, alternative embodiments of the bus subsystem may utilize multiple busses.

It will be readily apparent to one of ordinary skill in the art that many other hardware and software configurations are suitable for use with the present disclosure. For example, the computer 905 may be a desktop, portable, rack-mounted, or tablet configuration. Additionally, the computer 905 may be a series of networked computers. In still other embodiments, the techniques described above may be implemented upon a chip or an auxiliary processing board.

Various embodiments of the present disclosure can be implemented in the form of logic in software or hardware or a combination of both. The logic may be stored in a computer-readable or machine-readable non-transitory storage medium as a set of instructions adapted to direct a processor of a computer system to perform a set of steps disclosed in embodiments of the present disclosure. The logic may form part of a computer program product adapted to direct an information-processing device to perform a set of steps disclosed in embodiments of the present disclosure. Based on the disclosure and teachings provided herein, a person of ordinary skill in the art will appreciate other ways and/or methods to implement the present disclosure.

The data structures and code described herein may be partially or fully stored on a computer-readable storage medium and/or a hardware module and/or hardware apparatus. A computer-readable storage medium includes, but is not limited to, volatile memory, non-volatile memory, and magnetic and optical storage devices, such as disk drives, magnetic tape, CDs, DVDs, or other media, now known or later developed, that are capable of storing code and/or data. Hardware modules or apparatuses described herein include, but are not limited to, ASICs, FPGAs, dedicated or shared processors, and/or other hardware modules or apparatuses now known or later developed.

The methods and processes described herein may be partially or fully embodied as code and/or data stored in a computer-readable storage medium or device, so that when a computer system reads and executes the code and/or data, the computer system performs the associated methods and processes. The methods and processes may also be partially or fully embodied in hardware modules or apparatuses, so that when the hardware modules or apparatuses are activated, they perform the associated methods and processes. The methods and processes disclosed herein may be embodied using a combination of code, data, and hardware modules or apparatuses.

The embodiments disclosed herein are not to be limited in scope by the specific embodiments described herein. Various modifications of the embodiments of the present disclosure, in addition to those described herein, will be apparent to those of ordinary skill in the art from the foregoing description and accompanying drawings. Further, although some of the embodiments of the present disclosure have been described in the context of a particular implementation in a particular environment for a particular purpose, those of ordinary skill in the art will recognize that the disclosure's usefulness is not limited thereto and that the embodiments of the present disclosure can be beneficially implemented in any number of environments for any number of purposes.

What is claimed is:

1. A method for performing a lane margining test for a plurality of lanes of an interconnect link, the method comprising:
performing a parallel margin assessment phase of the lane margining test on the plurality of lanes concurrently to determine a collective baseline offset;
sequentially performing a serial margin assessment phase of the lane margining test on each lane starting at the collective baseline offset to determine a respective refined baseline offset for each lane beyond which a respective serial margin assessment phase fails for that lane; and
sequentially performing a fine-tuning margin assessment phase of the lane margining test on each lane starting at the respective refined baseline offset for that lane to determine a respective lane margin for that lane.

2. The method of claim 1, wherein the parallel margin assessment phase and the respective serial margin assessment phase for each lane are performed using a trimmed dwell time that is shorter than a target dwell time used to perform the respective fine-tuning margin assessment phase.

3. The method of claim 2, wherein the parallel margin assessment phase includes counting a number of errors occurring across all the lanes during the trimmed dwell time, and increasing a step count across all the lanes when the number of errors across all the lanes during the trimmed dwell time is less than a trimmed error threshold.

4. The method of claim 3, wherein the collective baseline offset is determined as a last step count after which the number of errors across all the lanes reaches or exceeds the trimmed error threshold.

5. The method of claim 2, wherein the serial margin assessment phase for an individual lane includes, starting at the collective baseline offset, counting a number of errors occurring on the individual lane during the trimmed dwell time, and increasing a step count when the number of errors on the individual lane during the trimmed dwell time is less than a trimmed error threshold.

6. The method of claim 5, wherein the respective refined baseline offset for the individual lane is determined as a last step count after which the number of errors of the individual lane reaches or exceeds the trimmed error threshold.

7. The method of claim 2, wherein the fine-tuning margin assessment phase for an individual lane includes, starting at the refined baseline offset, counting a number of errors that occur during the target dwell time.

8. The method of claim 7, wherein the fine-tuning margin assessment phase further includes increasing a step count when the number of errors on the individual lane at the refined baseline offset during the target dwell time is less than a target error threshold.

9. The method of claim 8, wherein the lane margin of the individual lane is determined as a last step count after which the number of errors on the individual lane during the target dwell time reaches or exceeds than the target error threshold.

10. The method of claim 7, wherein the fine-tuning margin assessment phase further includes decreasing the step count when the number of errors on the individual lane at the refined baseline offset during the target dwell time is above the target error threshold corresponding to the respective lane.

11. The method of claim 10, wherein the lane margin of the individual lane is determined as a lowest step count in which the number of errors on the individual lane during the target dwell time reaches or exceeds than the target error threshold.

12. The method of claim 1, wherein the lane margin corresponds to a voltage margin.

13. The method of claim 1, wherein the lane margin corresponds to a timing margin.

14. The method of claim 1, wherein the lane margining test is performed while the interconnect link is in a normal operational state.

15. A peripheral device comprising:
an interconnect to communicate with a host device; and
a memory coupled to the interconnect,
wherein applying a lane margining test to the interconnect includes:
performing a parallel margin assessment phase of the lane margining test on a plurality of lanes of the interconnect concurrently to determine a collective baseline offset;
sequentially performing a serial margin assessment phase of the lane margining test on each lane starting at the collective baseline offset to determine a respective refined baseline offset for each lane beyond which a respective serial margin assessment phase fails for that lane; and
sequentially performing a fine tuning margin assessment phase of the lane margining test on each lane starting at the respective refined baseline offset for that lane to determine a respective lane margin for that lane.

16. The peripheral device of claim 15, wherein the parallel margin assessment phase and the respective serial margin assessment phase for each lane are performed using a trimmed dwell time that is shorter than a target dwell time used to perform the respective fine tuning margin assessment phase.

17. The peripheral device of claim 16, wherein the parallel margin assessment phase includes:
counting a number of errors occurring across all the lanes during the trimmed dwell time; and
increasing a step count across all the lanes when the number of errors across all the lanes during the trimmed dwell time is less than a trimmed error threshold,
wherein the collective baseline offset is determined as a last step count after which the number of errors across all the lanes reaches or exceeds the trimmed error threshold.

18. The peripheral device of claim 16, wherein the serial margin assessment phase for an individual lane includes:
starting at the collective baseline offset, counting a number of errors occurring on the individual lane during the trimmed dwell time; and
increasing a step count when the number of errors on the individual lane during the trimmed dwell time is less than a trimmed error threshold,
wherein the respective refined baseline offset for the individual lane is determined as a last step count after which the number of errors of the individual lane reaches or exceeds the trimmed error threshold.

19. The peripheral device of claim 16, wherein the fine tuning margin assessment phase for an individual lane includes:
starting at the refined baseline offset, counting a number of errors that occur during the target dwell time; and
increasing a step count when the number of errors on the individual lane at the refined baseline offset during the target dwell time is less than a target error threshold,
wherein the lane margin of the individual lane is determined as a last step count after which the number of errors on the individual lane during the target dwell time reaches or exceeds than the target error threshold.

20. The peripheral device of claim 16, wherein the fine tuning margin assessment phase for an individual lane includes:
starting at the refined baseline offset, counting a number of errors that occur during the target dwell time; and
decreasing the step count when the number of errors on the individual lane at the refined baseline offset during the target dwell time is above the target error threshold corresponding to the respective lane,
wherein the lane margin of the individual lane is determined as a lowest step count after which the number of errors on the individual lane during the target dwell time reaches or exceeds than the target error threshold.
